(19) United States
(12) Patent Application Publication
(10) Pub. No.: US 2025/0226354 A1
(43) Pub. Date: Jul. 10, 2025

(54) APPARATUS FOR STACKING CHIP

(71) Applicant: Samsung Electronics Co., Ltd., Suwon-si (KR)

(72) Inventors: Ahra JO, Suwon-si (KR); Huijae KIM, Suwon-si (KR); Mingu LEE, Suwon-si (KR); Hongkyu KIM, Suwon-si (KR); Kangsan LEE, Suwon-si (KR); Youngkun JEE, Suwon-si (KR); Euisun CHOI, Suwon-si (KR); Sungjin HAN, Suwon-si (KR)

(73) Assignee: Samsung Electronics Co., Ltd., Suwon-si (KR)

(21) Appl. No.: 18/894,682

(22) Filed: Sep. 24, 2024

(30) Foreign Application Priority Data
Jan. 5, 2024 (KR) 10-2024-0002047

(51) Int. Cl. H01L 23/00

(52) U.S. Cl. CPC H01L 24/74; H01L 2224/74; H01L 2924/40

(57) ABSTRACT

An apparatus for stacking chips includes a bonding base moved to transfer and stack a chip and an attachment element disposed on a bottom of the bonding base and adsorbing the chip, wherein the attachment element includes a cavity through which air flows in and out to change the shape of the adsorbed chip, and the attachment element is deformed so that the chip gradually comes into contact with the buffer eventually in the entire surface of chip, starting from a center of the chip toward an edge of the chip, and then deformed so that only the edge of the chip is in contact with the buffer.

### CROSS-REFERENCE TO RELATED APPLICATION(S)

This application claims benefit of priority to Korean Patent Application No. 10-2024-0002047 filed on Jan. 5, 2024 in the Korean Intellectual Property Office, the disclosures of which are incorporated herein by reference in their entirety.

### BACKGROUND

The present inventive concepts relate to an apparatus for stacking chips.

In hybrid bonding processes, such as copper bonding (HCB) process, since adhesives or U-bumps are not used, voids may be very easily formed between two bonded interfaces. Such defects not only directly cause product defects, but also lead to copper migration in reliability evaluation from a long-term perspective.

In particular, in the case of multi-stack products, as the topology of each chip is accumulated, a surface flatness may deteriorate in a direction toward higher levels.

Therefore, there is a need to develop an apparatus for stacking chips that may reduce formation of voids during the bonding process when manufacturing a high bandwidth memory (HBM) using, e.g., a hybrid copper bonding (HCB) process.

### SUMMARY

An aspect of the present inventive concepts is to provide an apparatus for stacking chips, capable of reducing formation of voids during a bonding process.

According to an aspect of the present inventive concepts, an apparatus for stacking chips includes: a bonding base configured to support transferring and stacking a chip onto a buffer; and an attachment element on a bottom of the bonding base and configured to adsorb the chip, wherein the attachment element defines a cavity configured to change a shape of the attachment element and a shape of the adsorbed chip based on air flowing in and out of the cavity, and wherein the attachment element is configured to deform towards the chip such that the chip gradually comes into contact with a buffer starting from a center of the chip toward an edge of the chip, and to deform away from the buffer so that only the edge of the chip is in contact with the buffer.

According to an aspect of the present inventive concepts, an apparatus for stacking chips includes: a bonding base configured to support transferring and stacking a chip onto a buffer; and an attachment element on a bottom of the bonding base and configured to adsorb the chip, wherein the bonding base includes an air hole provided in a center of the bonding base, and a cavity having a connection portion connected to the air hole and an expansion portion connected to the connection portion at a lower portion of the connection portion, wherein the attachment element includes a thin film portion including an elastic material and disposed below the cavity, and wherein the thin film portion is configured such that a shape of the thin film portion deforms based on air supplied to the cavity through the air hole.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a configuration diagram illustrating an apparatus for stacking chips according to at least one embodiment; and

FIGS. 2 to 8 are diagrams illustrating the operation of an apparatus for stacking chips according to at least one embodiment.

### DETAILED DESCRIPTION

Hereinafter, embodiments of the present inventive concepts will be described with reference to the accompanying drawings, wherein like reference numerals designate like elements throughout the drawings and the specification. Additionally, in the drawings, sizes of elements in the drawings may be exaggerated for clarity and convenience of explanation.

Additionally, when the terms “about” or “substantially” are used in this specification in connection with a numerical value and/or geometric terms, it is intended that the associated numerical value includes a manufacturing tolerance (e.g., +10%) around the stated numerical value. Further, regardless of whether numerical values and/or geometric terms are modified as “about” or “substantially,” it will be understood that these values should be construed as including a manufacturing or operational tolerance (e.g., +10%) around the stated numerical values and/or geometry. Additionally, whenever a range of values is enumerated, the range includes all values within the range as if recorded explicitly clearly, and may further include the boundaries of the range. Accordingly, of “X” to “Y” provides a range including all values between X and Y, including X and Y.

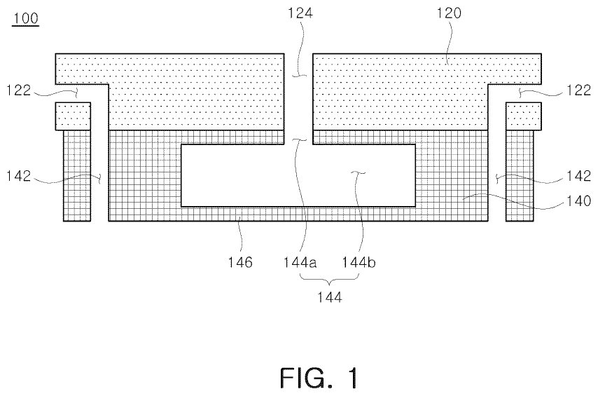

FIG. 1 is a configuration diagram illustrating an apparatus for stacking chips according to at least one embodiment.

Referring to FIG. 1, an apparatus 100 configured to stack chips according to at least one embodiment includes a bonding base 120 and an attachment element 140.

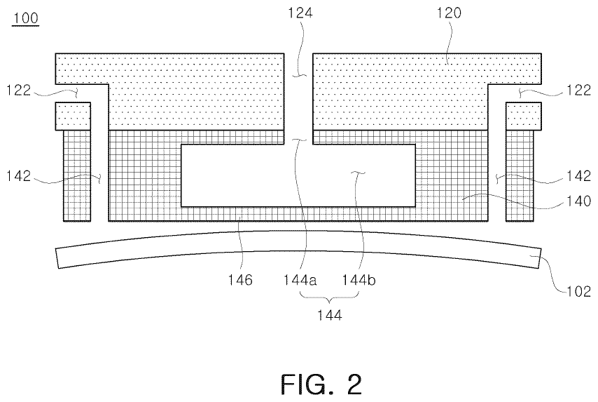

The bonding base 120 may be disposed on top of the attachment element 140. For example, the bonding base 120 may be glued to (and/or otherwise sealed to) the attachment element 140. Meanwhile, as an example, the bonding base 120 may be provided with a vacuum hole 122 configured to form a vacuum for adsorption of a chip (see FIGS. 2 to 8). As an example, the vacuum hole 122 may be open to a lower surface of the bonding base 120. In at least one embodiment, the vacuum hole 122 (open to the lower surface of the bonding base 120) may have a strip shape when viewed from below. However, the present inventive concepts are not limited thereto, and a plurality of vacuum holes 122 may be spaced apart from each other along a strip shape when viewed from below. Meanwhile, a vacuum pump (not shown) may be connected to the vacuum hole 122.

In addition, an air hole 124 may be provided in a center region of the bonding base 120 and be configured to supply air for deformation of the attachment element 140 to be described below. Meanwhile, in the present embodiment, a case in which one air hole 124 is provided in the bonding base 120 is illustrated in the drawing as an example, but the examples are not limited thereto. For example, a plurality of air holes 124 may be arranged to be spaced apart from each other. In addition, an air pump (not shown) may be connected to the air hole 124 and may be configured to supply and/or discharge air through the air hole 124.

Meanwhile, the bonding base 120 may be formed of a material that resists deformation (e.g., which may not be deformed at operating pressures) in order to prevent deformation when air enters and exits through the air hole 124 and when vacuum is provided or removed through the vacuum hole 122.

Also, the bonding base 120 may be configured to be raised and lowered for stacking a chip 102. In addition, the bonding base 120 may be moved in a horizontal direction for transferring the chip 102. To this end, a driving unit (not shown) may be connected to the bonding base 120. In at least one example, the driving unit may include, e.g., a motor, a piston, a gear train, etc., configured to position the bonding base 120. In this manner, the bonding base 120 may be connected to the driving unit so that chips may be transferred and stacked.

The attachment element 140 may be installed on the bottom of the bonding base 120. Meanwhile, the attachment element 140 may be provided with a connection hole 142 connected to the vacuum hole 122 of the bonding base 120. The connection hole 142 may be open through the bottom of the attachment element 140. The connection hole 142 and the vacuum hole 122 may have the same and/or a different shape. As an example, the connection hole 142 may have a strip shape when viewed from below. However, without being limited thereto, a plurality of connection holes 142 may be spaced apart from each other along the strip shape when viewed from below. Accordingly, the connection hole 142 may adsorb the edge of the chip 102. Meanwhile, the attachment element 140 may include a cavity 144 connected to the air hole 124 of the bonding base 120. The cavity 144 may include a connection portion 144a connected to the air hole 124 of the bonding base 120 and an expansion portion 144b disposed below the connection portion 144a. Meanwhile, the attachment element 140 may be formed of an elastic material configured to be deformed when air is supplied to the cavity 144 and/or to reform when air is discharged from the cavity 144. For example, in at least one embodiment, elastic material of the attachment element 140 may be selected based on the elasticity of the selected material, such that air pressure resulting from the supply of air to the cavity 144 (e.g., from an air pump) elastically deforms the attachment element 140 between a first deformed state (e.g., through positive air pressure) and a second deformed state (e.g., through negative air pressure), and such that the attachment element 140 returns to a neutral state when the air pressure is no longer being applied. In at least one embodiment, the cavity 144 may further be connected to a valve configured to control, e.g., the release of air pressure from the cavity. In addition, the attachment element 140 may be provided with a thin film portion 146 disposed below the expansion portion 144b. In addition, when air is supplied to or discharged from the cavity 144, the thin film portion 146 may be deformed, thereby changing the shape of the chip 102, as described in further detail below.

As described above, the attachment element 140 may be deformed by air being supplied to or discharged from the cavity 144 while the chip 102 is attached to the attachment element 140. Accordingly, stacking of the chip 102 may be performed, while the chip 102 is deformed together with the attachment element 140 due to deformation of the attachment element 140.

Hereinafter, an operation of an apparatus for stacking chips according to at least one embodiment will be described with reference to the drawings.

FIGS. 2 to 8 are diagrams illustrating an operation of an apparatus for stacking chips according to at least one embodiment.

First, as shown in FIG. 2, when a vacuum is formed in the vacuum hole 122 of the bonding base 120 and the connection hole 142 of the attachment element 140, the chip 102 is attached to the bottom of the attachment element 140. At this time, the chip 102 may be referred to as being adsorbed to the bottom of the attachment element 140 while the attachment element 140 and the chip 102 are not deformed.

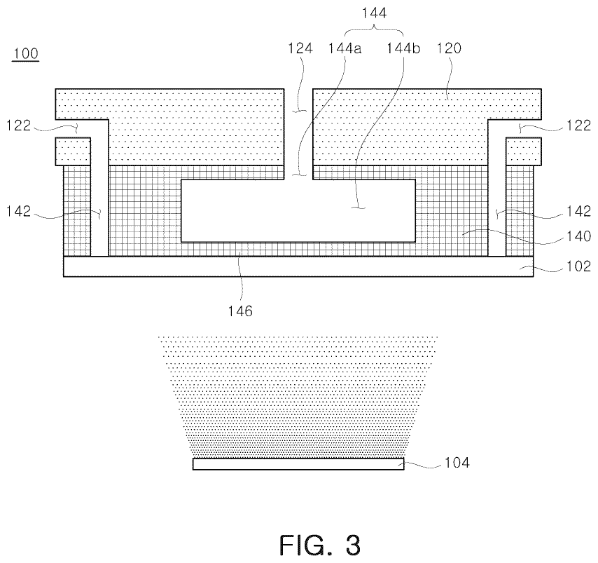

Thereafter, as shown in FIG. 3, the bonding base 120 is moved and the bottom of the chip 102 is imaged by a vision sensor 104. Thereafter, data collected by the vision sensor 104 is used to determine whether the bottom of the chip 102 imaged by the vision sensor 104 maintains a flat shape. In at least one embodiment, the vision sensor 104 may include one or more cameras configured to determine the flatness of the bottom of the chip 102.

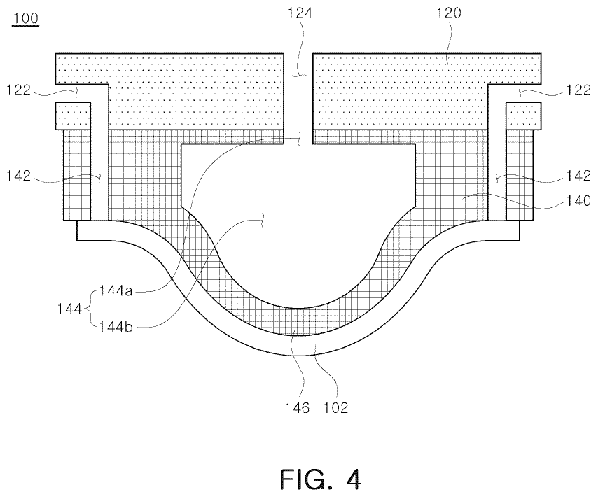

Thereafter, as shown in FIG. 4, air is supplied to the cavity 144 of the attachment element 140. Accordingly, the size of the cavity 144 of the attachment element 140 increases and the thin film portion 146 of the attachment element 140 is deformed. At this time, the cavity 144 may be referred to as having a substantially pentagonal cross-section (e.g., having a substantially flat upper wall, a substantially flat left and right wall, and a curved lower surface including two sides differentiated by a change in slope therebetween), and accordingly, the thin film portion 146 of the attachment element 140 may protrude downwardly. Accordingly, the chip 102 adsorbed on the bottom of the attachment element 140 may also be deformed to have a shape corresponding to the shape of the thin film portion 146.

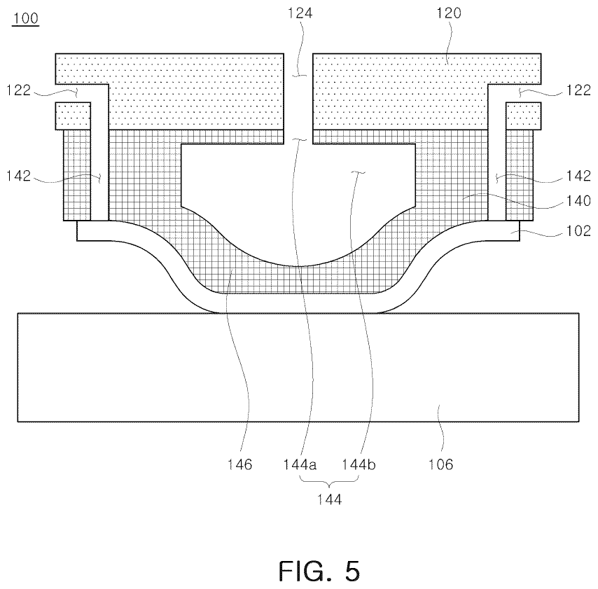

Thereafter, as shown in FIG. 5, the bonding base 120 is moved so that the center of the chip 102 comes into contact with a buffer 106. Accordingly, the chip 102 is brought into contact with the buffer 106 so that the center of the chip 102 is flat. Accordingly, the size of the cavity 144 of the attachment element 140 is reduced. To this end, air may escape from the cavity 144. At this time, the pressure of air applied to the cavity 144 may be, as an example, 50 Kpa to 400 Kpa, and the center of the chip 102 may be first brought into contact with the buffer 106 due to the cavity 144 protruding due to a relatively high pressure.

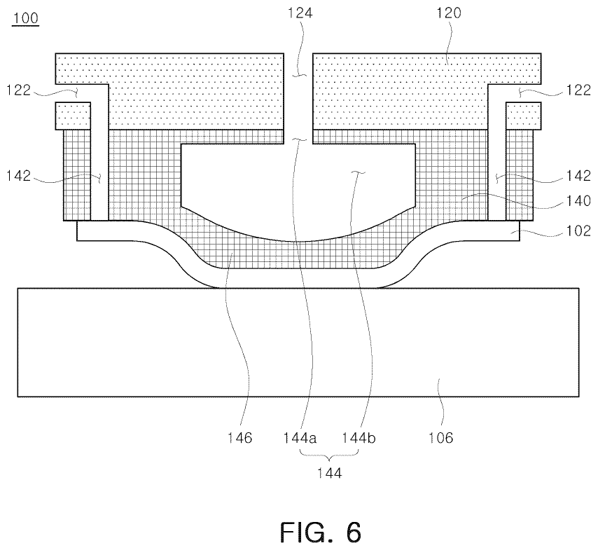

Thereafter, as shown in FIG. 6, the size of the cavity 144 of the attachment element 140 is reduced to increase a contact area between the chip 102 and the buffer 106. To this end, air may escape from the cavity 144. At this time, the pressure of air applied to the cavity 144 may gradually decrease. As an example, the pressure of air at this time may gradually decrease from, e.g., 400 Kpa to 50 Kpa. Accordingly, the chip 102 may be brought into contact with the buffer 106 sequentially from the center of the chip 102 to the edge of the chip 102. In at least one embodiment, a valve may be connected to the cavity 144 to control the rate of change in the pressure of air.

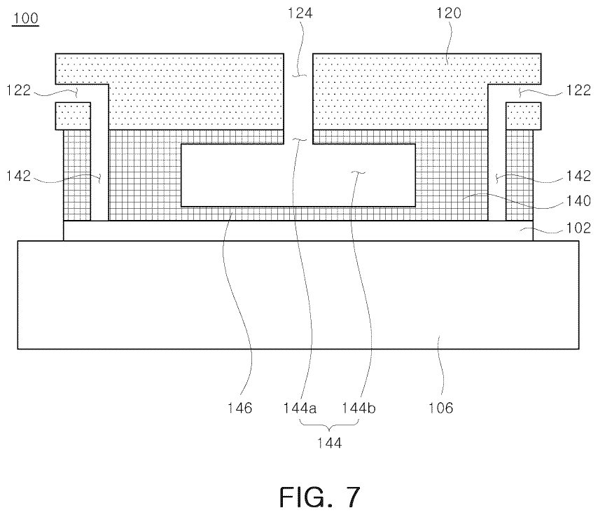

Thereafter, as shown in FIG. 7, the cavity 144 is restored to its original shape so that the chip 102 has a flat shape. At this time, the thin film portion 146 may also have a flat shape. At this time, the pressure applied to the cavity 144 may be, for example, 20 Kpa to 50 Kpa, and due to the shape of the flat thin film portion 146, even pressure may be applied to the entire surface of the chip 102.

In this manner, the chip 102 is sequentially contacted from the center toward the edge, thereby preventing the occurrence of a void.

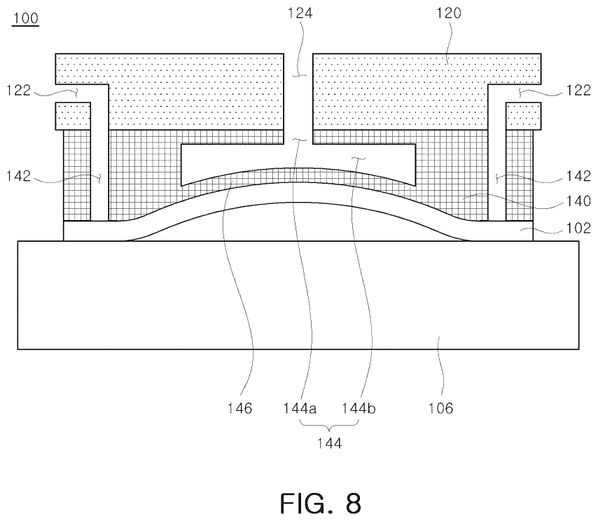

Thereafter, as shown in FIG. 8, the size of the cavity 144 decreases so that the edge of the chip 102 contacts the buffer 106 and the center of the chip 102 is spaced apart from the buffer 106. For example, a negative air pressure may be applied to the cavity 144 to reduce the size of the cavity 144. At this time, as air escapes from the cavity 144, the thin film portion 146 of the attachment element 140 recedes upwardly to have a concave shape. Accordingly, only the edge of the chip 102 may receive strong pressure by the driving unit. At this time, the pressure of air applied to the cavity 144 may be, as an example, 20 Kpa or less. And, the pressure applied to the chip 102 by the driving unit may be maintained constant. Accordingly, even if a void occurs between the edge of the chip 102 and the buffer 106, the void may be removed (e.g., without being limited to a specific mechanism, through cavitation of the void).

Afterwards, apparatus 100 may be removed from the chip 102, e.g., by returning the air pressure in the vacuum hole 122, the connection hole 142, and/or the cavity 144 to a neutral air pressure (e.g., atmospheric pressure and/or an ambient pressure).

In at least one embodiment, the operations of the apparatus 100 may be controlled by processing circuitry, such as hardware including logic circuits; a hardware/software combination such as a processor executing software; or a combination thereof, configured to control the operation of the apparatus 100. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. Additionally, the apparatus 100 may be included in a chip processing apparatus including at least one processor and memory storing instructions, which when executed by the at least processor, control the activation, timing, operation, intensity, etc. of the driving unit, the air pump, the vision sensor, the valve, etc. connected to the apparatus 100.

As described above, the chip 102 is bonded to the buffer 106 from the center to the edge thereof, and then the edge of the chip 102 is pressed again, thereby preventing the occurrence of a void due to a phase difference.

The apparatus for stacking chips configured to reduce the occurrence of voids during the bonding process may be provided.

While embodiments have been shown and described above, it will be apparent to those skilled in the art that modifications and variations could be made without departing from the scope of the present inventive concepts as defined by the appended claims.

What is claimed is:

1. An apparatus for stacking chips, the apparatus comprising:
a bonding base configured to support transferring and stacking a chip onto a buffer; and
an attachment element on a bottom of the bonding base and configured to adsorb the chip,
wherein the attachment element defines a cavity configured to change a shape of the attachment element and a shape of the adsorbed chip based on air flowing in and out of the cavity, and
wherein the attachment element is configured to deform towards the chip such that the chip gradually comes into contact with a buffer starting from a center of the chip toward an edge of the chip, and to deform away from the buffer so that only the edge of the chip is in contact with the buffer.

2. The apparatus of claim 1, wherein the bonding base defines an air hole in a center of the bonding base, and
the air hole is connected to the cavity through which air flows.

3. The apparatus of claim 2, wherein the cavity includes
an expansion portion configured to be deformed, and
a connection portion connecting to the connection portion to the air hole.

4. The apparatus of claim 3, wherein the attachment element includes a thin film portion below the expansion portion and configured to deform in conjunction with the deformation of the expansion portion.

5. The apparatus of claim 4, wherein at least the thin film portion includes an elastic material.

6. The apparatus of claim 5, wherein the thin film portion is configured to be deformed to be convex toward a lower side of the attachment element when air is supplied to the expansion portion.

7. The apparatus of claim 6, wherein the thin film portion is configured to be deformed to be concave when air is discharged from the expansion portion.

8. The apparatus of claim 1, wherein the bonding base defines a vacuum hole configured to provide a vacuum such that that the chip is adsorbed to a bottom of the attachment element.

9. The apparatus of claim 8, wherein the attachment element defines a connection hole connected to the vacuum hole.

10. The apparatus of claim 9, wherein
the connection hole is open to the bottom of the attachment element, and
the connection hole comprises a strip shape when the attachment element is viewed from a lower side.

11. The apparatus of claim 10, wherein the connection hole is configured to adsorb to the edge of the chip.

12. The apparatus of claim 1, wherein
the chip is bonded to the buffer, and
the chip is pressed so that the center of the chip contacts the buffer first, and then the edge of the chip sequentially contacts the buffer.

13. The apparatus of claim 12, wherein, after the edge of the chip is pressed to contact the buffer, the chip has a flat shape.

14. The apparatus of claim 13, wherein, after the chip in the flat shape is pressed to contact the buffer, the center of the chip is deformed to be concave so that only the edge of the chip is pressed against the buffer.

15. The apparatus of claim 14, wherein the apparatus is configured such that a pressure of the air applied to the cavity when the center of the chip is pressed to contact the buffer is greater than the pressure of the air applied to the cavity when the edge of the chip is pressed to contact the buffer.

16. The apparatus of claim 15, wherein the apparatus is configured such that the pressure of the air applied to the cavity when the chip has the flat shape is greater than the pressure of the air applied to the cavity when only the edge of the chip is pressed against the buffer.

17. The apparatus of claim 16, wherein the apparatus is configured such that the pressure of the air applied to the cavity when only the edge of the chip is pressed against the buffer is maintained to be constant while only the edge of the chip is pressed.

18. The apparatus of claim 12, wherein apparatus is configured such that the pressure of the air applied to the cavity gradually decreases between when the center of the chip is pressed to the buffer and when the edge of the chip sequentially contacts the buffer.

19. An apparatus for stacking chips, the apparatus comprising:
a bonding base configured to support transferring and stacking a chip onto a buffer; and
an attachment element on a bottom of the bonding base and configured to adsorb the chip,
wherein the bonding base includes
an air hole provided in a center of the bonding base, and
a cavity having a connection portion connected to the air hole and an expansion portion connected to the connection portion at a lower portion of the connection portion,
wherein the attachment element includes a thin film portion including an elastic material and disposed below the cavity, and
wherein the thin film portion is configured such that a shape of the thin film portion deforms based on air supplied to the cavity through the air hole.

20. The apparatus of claim 19, wherein the thin film portion is configured to be deformed to be convex toward a lower side of the attachment element when air is supplied to the expansion portion, and to be deformed to be concave when air is discharged from the expansion portion.
